(19) United States
(12) Patent Application Publication
(10) Pub. No.: US 2012/0139033 A1
(43) Pub. Date: Jun. 7, 2012

(54) SEMICONDUCTOR DEVICE AND METHOD OF MANUFACTURING THE SAME

(75) Inventors: Hiroyuki Yamasaki, Somers, NY (US); Hideshi Miyajima, Clifton Park, NY (US); Yoshihiro Uozumi, Somers, NY (US)

(73) Assignee: TOSHIBA AMERICA ELECTRONIC COMPONENTS, INC., Irvine, CA (US)

(21) Appl. No.: 12/961,762

(22) Filed: Dec. 7, 2010

(51) Int. Cl. H01L 29/78; H01L 21/76

(52) U.S. Cl. 257/327; 438/429; 257/E21.54; 257/E29.255

(57) ABSTRACT

Semiconductors devices and methods of making semiconductor devices are provided. According to one embodiment, a semiconductor device can include a p-type field effect transistor area having an active region with an epitaxial layer grown thereupon and an isolation feature adjacent to the active region. A height of the isolation feature equals or exceeds a height of an interface between the epitaxial layer and the active region. More particularly, a height of the isolation feature in the corner of a junction between the isolation feature and the action region equals or exceeds the height to the interface between the epitaxial layer and the active region.

### FIELD

Embodiments described herein relate generally to semiconductor devices and method for fabricating semiconductor devices.

### BACKGROUND

Silicon large-scale integrated circuits, among other device technologies, are increasing in use in order to provide support for the advanced information society of the future. An integrated circuit can be composed of a plurality of semiconductor devices, such as transistors or the like, which can be produced according to a variety of techniques. To continuously increase integration and speed of semiconductor devices, a trend of continuously scaling semiconductors (e.g., reducing size and features of semiconductor devices) has emerged. Reducing semiconductor and/or semiconductor feature size provides improved speed, performance, density, cost per unit, etc. of resultant integrated circuits. However, as semiconductor device and device features have become smaller and more advanced conventional fabrication techniques have been limited in their ability to produce finely defined features. Moreover, scaling limitations are introduced as semiconductors continue to scale down.

By way of example, various techniques facilitate scaling of integrated circuits. One technique is shallow trench isolation. Shallow trench isolation is an integrated circuit feature that prevents electrical current leakage between adjacent semiconductor devices. Conventional shallow trench isolation fabrication can include depositing apad oxide and a protective nitride layer over a semiconductor substrate. An opening can be formed in the protective nitride layer and the semiconductor substrate can be etched to form a trench. The trench can be filled with a dielectric, such as silicon dioxide for example. Planarization can occur followed by removal of the protective nitride and pad oxide. Subsequently, active areas for semiconductor devices can be developed.

Another technique involves adjusting a threshold voltage of a transistor (e.g., a metal-oxide-semiconductor field effect transistor (MOSFET) and in particular a high-K/metal MOSFET) by introducing a mismatched semiconductor lattice on top of the substrate via epitaxy. Introduction of an epitaxial layer also introduces strain to a silicon lattice which increases carrier (e.g., electron and/or hole) mobility to facilitate scaling. Epitaxy is a process involving growing a single-crystalline film of material on a single-crystalline substrate or wafer.

Depositing an epitaxial layer on an active area adjacent to a shallow trench isolation feature involves masking, epitaxial growth, and cleaning steps. During such cleaning steps, portions of the shallow trench isolation feature are isotropically removed leaving a void or divot in the insulating material. Divots can introduce current leakage and/or shorting. As divots increase is size and/or depth, increased degradation due to junction leakage can result. Accordingly, it would be desirable to implement techniques for producing semiconductor devices having epitaxial layers with reduced divot formation.

### BRIEF DESCRIPTION OF THE DRAWINGS

FIG. 1 is a cross-sectional image from a transmission electron microscope of a semiconductor device fabricated with a conventional process.

FIG. 2 is top down illustration of an example SRAM bit cell in accordance with various embodiments of the subject innovation.

FIG. 3 is a top down image from a scanning electron microscope of an example SRAM integrated circuit and a cross-sectional image from a transmission electron microscope of a portion of the SRAM integrated circuit in accordance with various embodiment of the subject innovation.

FIG. 4 illustrates a conventional semiconductor fabrication process and resultant semiconductor devices.

FIGS. 5 to 9 illustrate the steps of a conventional process to form an epitaxial layer and resultant semiconductor devices.

FIGS. 10 to 14 illustrate the steps of a process to form an epitaxial layer and the resultant semiconductor devices in accordance with various embodiments of the subject innovation.

FIG. 15 is a cross-sectional image from a transmission electronic microscope of a semiconductor device fabricated in accordance with various embodiments of the subject innovation.

FIG. 16 illustrates a first example methodology for fabricating a semiconductor device in accordance with an embodiment of the subject innovation.

FIG. 17 is a flow diagram of a second example methodology for fabricating a semiconductor device in accordance with an embodiment of the subject innovation.

### DETAILED DESCRIPTION

The subject innovation provides a semiconductor device having an epitaxial layer formed on an active region adjacent to an isolation feature. In various embodiments, a height of the isolation feature equals or exceeds a height of an interface between the epitaxial layer and the active region. More particularly, a height of the isolation feature in the corner of a junction between the isolation feature and the action region equals or exceeds the height to the interface between the epitaxial layer and the active region, thereby reducing leakage. In further embodiments, methods of fabricating semiconductor devices according to at least the above are provided.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

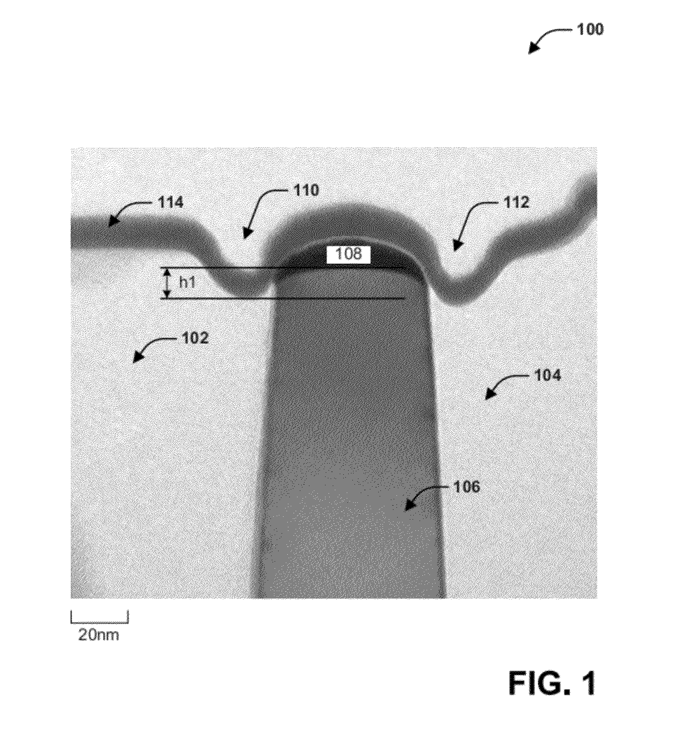

Referring first to FIG. 1, a cross-sectional image 100, from a transmission electron microscope, of a semiconductor device fabricated according to a conventional process. Depicted in image 100 are a first isolation feature 102 and a second isolation 104. In an example, the isolation features 102 and 104 can be fabricated via shallow trench isolation (STI). Between the first isolation feature 102 and the second isolation feature 104 is silicon substrate 106. More particularly, an active region or channel region of the silicon substrate 106 is depicted in image 100. In an aspect, first isolation feature 102 and second isolation feature 104 operate to a segregate or separate channel region of silicon substrate 106 from other active regions (not shown) of silicon substrate 106. An epitaxial layer 108 is located on top of the silicon substrate 106. According to an embodiment, the epitaxial layer 108 can be a heteroepitaxial layer. For instance, silicon substrate 106 can include crystalline silicon and epitaxial layer 108 includes crystalline silicon-germanium (SiGe). As the epitaxial layer 108 (e.g., SiGe layer) is on channel region or active region of silicon substrate 106, it can be denoted as a cSiGe layer.

During the process to grow epitaxial layer 108 on the silicon substrate 106, the silicon substrate 106 and isolation features 102 and 104 undergo a plurality of a masking, etching, and/or cleaning steps. The steps can remove portions of the first isolation feature 102 and the second isolation feature 104. As shown in image 100, removal of portions of the isolation features generate respective divots 110 and 112 in the first isolation feature 102 and the second isolation feature 104. Image 100 depicts a height difference, h1, between the bottom of divot 110 and an interface between the silicon substrate 106 and the epitaxial layer 108. In addition, when divots 110 and/or 112 are large, a pre-bake step of the epitaxial process (e.g., typically at 800 C in a hydrogen atmosphere), can enhance corner rounding of the silicon substrate 106.

The bottom of divot 110 can also be referred to as a height of the first isolation feature 102 at a corner of a junction between the first isolation feature 102 and the silicon substrate 106. In image 100, h1 is approximately 10 nanometers (nm). However, it is to be appreciated that the height difference can vary depending on the particular processing methods and systems employed to fabricate the semiconductor device. In another embodiment, a height difference between a bottom of divot 112 and the interface of the silicon substrate 106 and the epitaxial layer 108 can be equal to height difference, h1. However, it is to be appreciated that variations in depths of divots 110 and 112 can be exhibited.

As the height difference, h1, increases, junction leakage also increases. According to an embodiment, the semiconductor device depicted in image 100 can comprise a p-type field effect transistor (PFET). Accordingly, the junction leakage can occur at a P+/P-Well junction. Such a PFET semiconductor device can be incorporated into a static random access memory (SRAM) device.

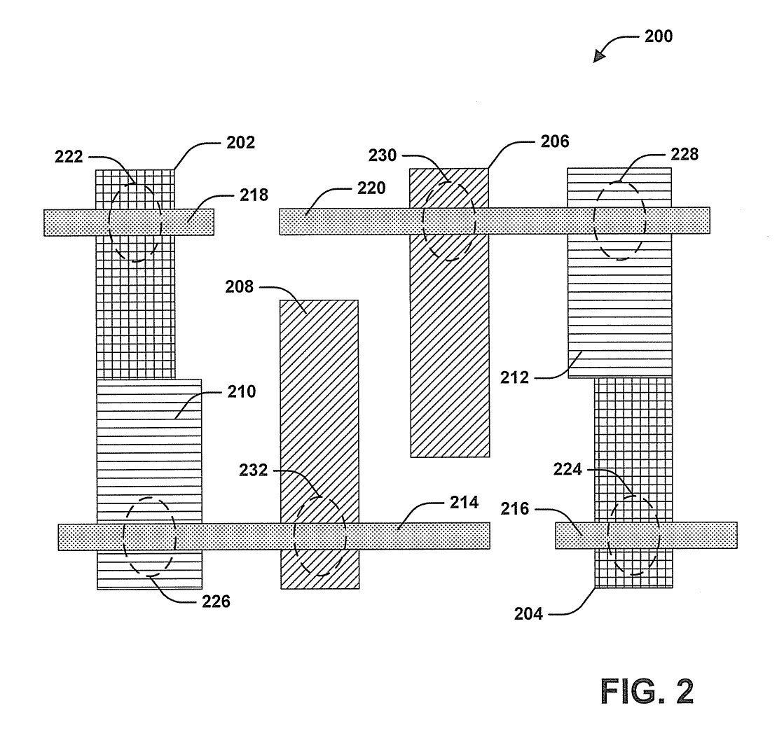

Turning to FIG. 2, a top down illustration of an example SRAM bit cell 200 in accordance with various embodiments of the subject innovation is provided. SRAM is a type of high speed, low power volatile memory that, unlike dynamic RAM, does not require periodic refresh of stored data. FIG. 2 depicts a cell 200 including active regions, isolation regions, and gate structures. Cell 200 includes 6 transistors: 2 pull-up transistors, 2 pull-down transistors, and 2 pass gate transistors. More particularly, cell 200 includes an active region 202 of a first pass gate transistor 222 and an active region 204 of a second pass gate transistor 224. Respectively corresponding to active region 202 and active region 204 are gate structures 218 and 216, which construct the 2 pass gate transistors 222 and 224 of cell 200, respectively. Cell 200 further includes active regions 206 and 208 of a first pull-up transistor 230 and a second pull-up transistor 232, respectively. In addition, active region 210 and active region 212 respectively provide a first pull-down transistor 226 and a second pull-down transistor 228. Gate structure 214 provides gates of second pull-up transistor 232 and first pull-down transistor 226. Similarly, gate structure 220 provides the gates of first pull-up transistor 230 and second pull-down transistor 228.

In an embodiment, active regions 202, 204, 210, and 212 are formed within a substrate (e.g., a silicon substrate) and doped with impurities. For instance, active regions 202, 204, 210, and 212 can be formed by doping the substrate with n-type impurities. Accordingly, first pass gate transistor 222, second pass gate transistor 224, first pull-down transistor 226, and second pull-down transistor 228 can be n-type or n-channel transistors. Such transistors are also referred to as n-type metal-oxide-semiconductor (nMOS) transistors, nMOSFET transistors, NFET transistors, or the like. Active regions 206 and 208 can be formed by doping the substrate with p-type impurities. Accordingly, first pull-up transistor 230 and second pull-up transistor 232 can be p-type or p-channel transistors. Such transistors are also referred to as p-type MOS (pMOS) transistors, pMOSFET transistors, PFET transistors, or the like.

In cell 200, active regions 202 and 210 can be a common active region. Similarly, active regions 204 and 212 can be common. Thus, first pass gate transistor 222 and first pull-down transistor 226 form without isolation therebetween. In addition, second pass gate transistor 224 and second pull-down transistor 228 exist without isolation therebetween. Isolation regions, however, separate active region 208 from other active regions and separate active region 206 from other active regions. Accordingly, the first and second pull-up transistors 230 and 232 stand isolated.

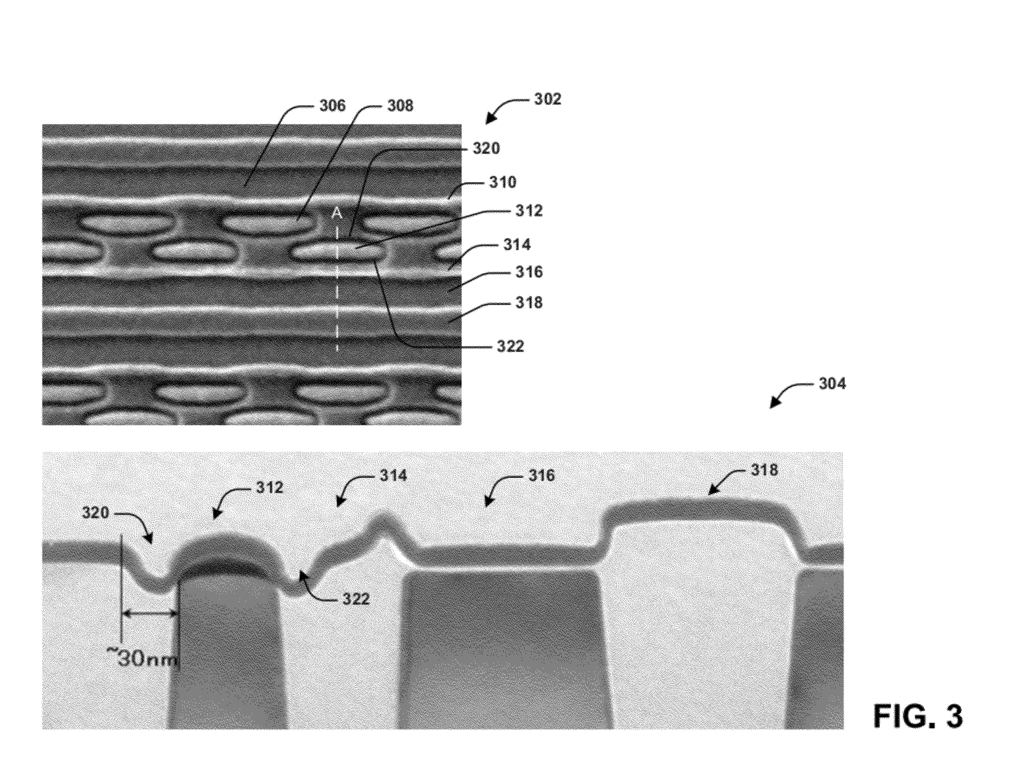

In another embodiment, the PFET depicted in FIG. 1, can be employed to implement the first pull-up transistor 230 and the second pull-up transistor 232 of SRAM cell 200. To this end, FIG. 3 shows a top down image 302 from a scanning electron microscope of an example SRAM integrated circuit and a cross-sectional image 304 from a transmission electron microscope of a portion of the SRAM integrated circuit in accordance with various embodiment of the subject innovation. Image 302 depicts a plurality of six-transistor SRAM cells as described above with respect to FIG. 2. Image 302 depicts a first active region 306 having a n-type impurity. First active region 306 can support formation of n-type transistors such as pass gate transistors and pull-down transistors of an SRAM cell. Further depicted is a second active region 308, separated from the first active region 306 by an isolation region 310. The second active region 308 can include p-type impurities to form a basis for a p-type transistor such as a pull-up transistor of an SRAM cell. A third active region 312, doped with p-type impurities, supports a second pull-up transistor of the SRAM cell. An isolation region 314 separates the third active region 312 from a fourth active region 316 having n-type impurities for a second pass gate transistor and a second pull-down transistor of the SRAM cell. An additional isolation region 318 separates adjacent SRAM cells along a first direction.

Isolation regions can surround the second active region 308 and the third active region 312. At a junction between the third active region 312 and the surrounding isolation regions, a first divot 320 and a second divot 322 can form during fabrication of the third active region 312. Although referred to as distinct divots, the first divot 320 and the second divot 322 can consist of disparate portions a single divot forming a ring around the third active region 312.

Image 304 depicts a cross-section image of the SRAM cell along line A shown in the top down image 302. In image 304, first divot 320 has a width of approximately 30 nm. However, it is to be appreciated that first divot 320 can have a width greater than or lesser than 30 nm, depending on the particular fabrication process implemented to fabricate third active region 312. First divot 320 and second divot 322 can generate leakage and/or shorting between pull-up transistors of the SRAM cell. For instance, divots of second active region 308 and divots of third active region 312 can reach a size sufficient to increase leakage and/or shorting between the second active region 308 and the third active region 312.

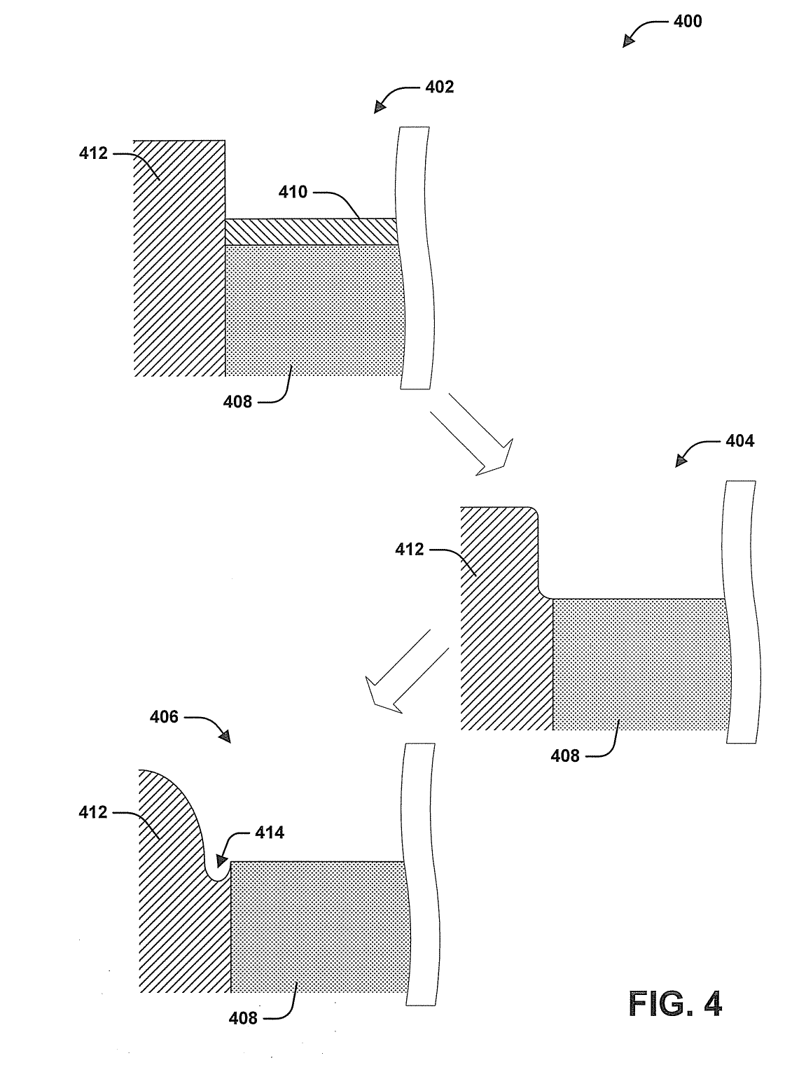

Turning to FIG. 4, depicted is a conventional semiconductor fabrication process 400 and resultant semiconductor devices that illustrate propagation of a divot. A portion 402, of a semiconductor device, includes a silicon substrate 408, an oxide layer 410, and an isolation feature 412. In an embodiment, a shallow trench isolation fabrication process can generate the isolation feature 412. Accordingly, a dielectric material, such as an oxide, forms the isolation feature 412. In addition, oxide layer 410 can comprise an oxide hard mask and silicon substrate 408 can be an active region of the substrate.

A PFET, such as a pull-up transistor of a SRAM cell, can be fabricated via epitaxy. In particular, a epitaxial layer can be grown on the silicon substrate 408. To grow an epitaxial layer, a first step is to etch the oxide layer 410 to expose a surface (e.g., a channel region) of the silicon substrate 408. In an embodiment, a wet etch process removes the oxide layer 410. With a wet etch, portions of the isolation feature 412 can be isotropically removed. Portion 404 depicts a resultant portion of the semiconductor device following the wet etch. After the wet etch, oxide layer 410 is removed and isolation feature 412 is partially removed. More particularly, isolation feature 412 laterally retreats during the wet etch process.

Prior to epitaxial growth, a pre-clean step facilitates improving the surface of silicon substrate 408. For successful epitaxial growth, an amount of defects and contaminants on the channel region of silicon substrate 408 should be minimized. Pre-cleaning can include subjecting portion 404 to an RCA clean, or other suitable cleaning, followed by a hydrofluoric acid dip and a deionized water rinse. However, it is to be appreciated that other pre-clean processes can be employed to prepare a surface of silicon substrate 408 for epitaxy. After pre-cleaning, the portion 404 can undergo a pre-bake process. During pre-bake, portion 404 is subjected to a hydrogen atmosphere and heated. While the pre-cleaning and/or pre-baking steps provide an optimal surface for epitaxial growth, these steps can erode the integrity of isolation features. For example, pre-cleaning and pre-baking can lead to formation of a divot 414 in isolation feature 412.

In addition, as shown in FIG. 4, preparation of the channel region of silicon substrate 408 for epitaxy results in a lateral retreat of isolation feature 412 from the silicon substrate 408. The lateral retreat, in turn, facilitates divot growth. Accordingly, suppressing lateral retreat can enable a reduction in a size of divot 414.

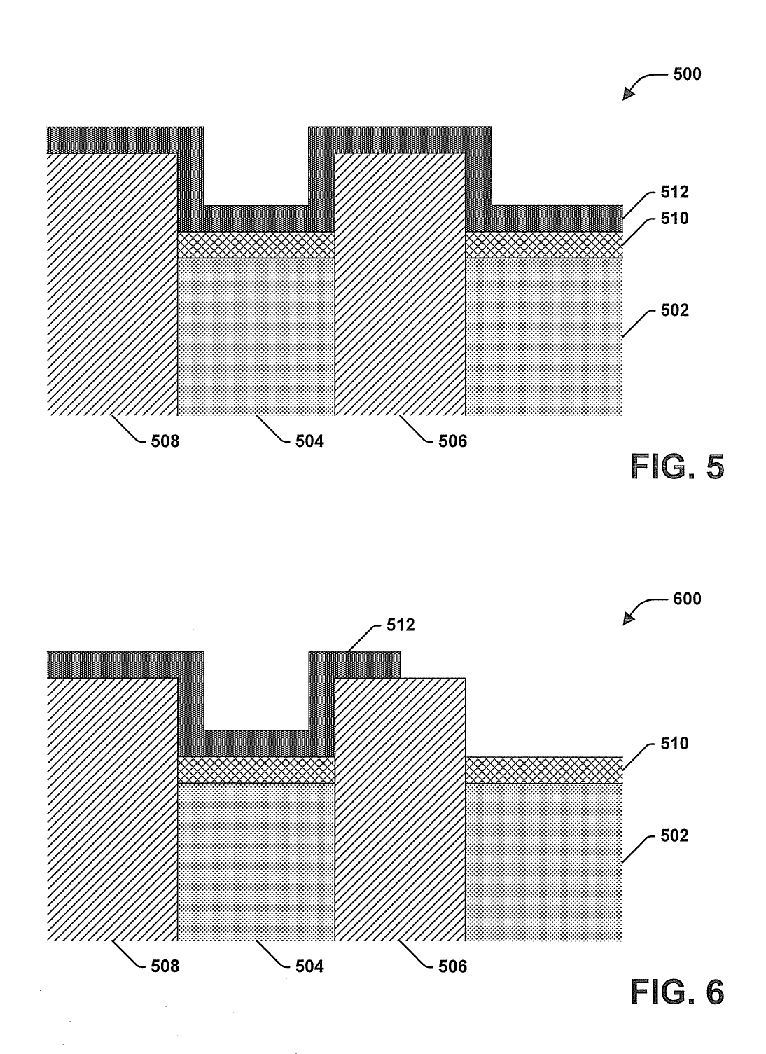

Turning next to FIGS. 5-9, various techniques of a conventional process for fabricating an epitaxial layer of a p-type field effect transistor and resultant semiconductor devices are illustrated. With reference first to FIG. 5, a first example step of epitaxial layer fabrication in accordance with a conventional process is illustrated via diagram 500. As diagram 500 illustrates, upon formation of a first isolation feature 506 and a second isolation feature 508, for example by STI fabrication, an oxide mask layer 510 can coat a first active silicon region 502 and a second active silicon region 504. Further, a protective nitride layer can cover the entirety of the isolation features 506 and 508 as well as the active regions 502 and 504.

In a specific, non-limiting example, it is desired to grow an epitaxial layer on first active region 502. Accordingly, the protective nitride layer can be selectively etched over the first active region 502 as shown in diagram 600 of FIG. 6. In an example, reactive ion etching (RIE) removes the protective nitride layer from the first active region 502.

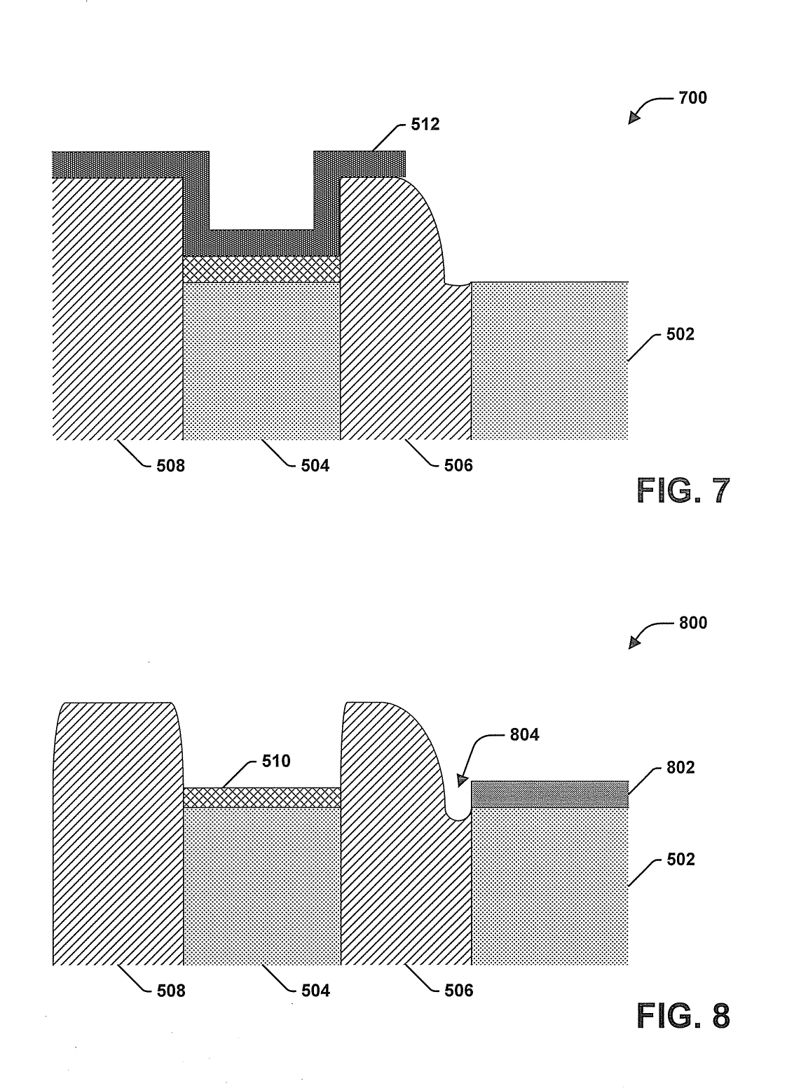

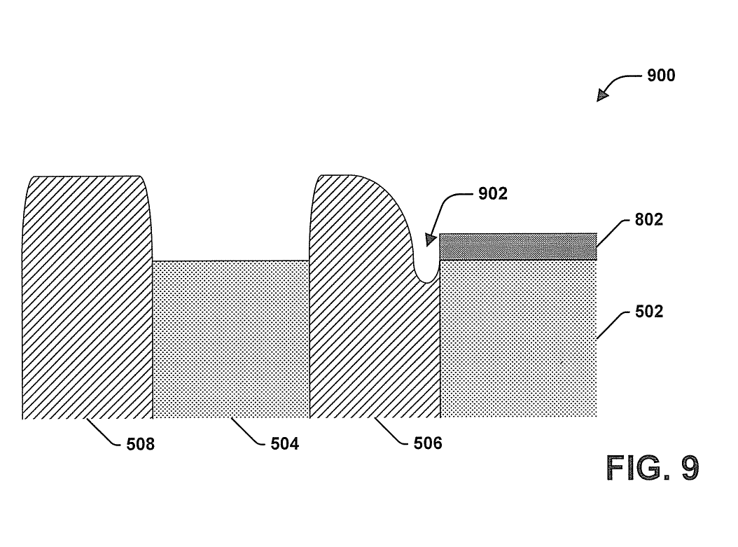

Diagram 700 of FIG. 7 illustrates a result after a wet etch of the oxide layer 510. As diagram 700 illustrates, the wet etch step remove the oxide layer 510 from the first active region 502. In addition, the wet etch removes a portion of the first isolation feature 506. Diagram 800 of FIG. 8 illustrates a result after deposition of an epitaxial layer 802 on the first active region 502. In preparation of deposition of epitaxial layer 802, the protective nitride layer 512 can be peeled. For instance, phosphoric acid (H₃PO₄) can be employed to peel the protective nitride layer 512 and phosphoric acid can also etch the epitaxial layer 802. Accordingly, in one embodiment, the protective nitride layer 512 is peeled prior to epitaxy.

In an example, epitaxial layer 802 can include a silicon-germanium (SiGe). In another example, carbon can be implanted into the epitaxial layer 802 to form a carbon-silicon-germanium material (cSiGe). Accordingly, epitaxial layer 802 can be referred to a as a heteroepitaxial layer. Prior to growing the epitaxial layer 802, pre-cleaning and/or pre-baking steps can occur, leading to further erosion of the first isolation feature 506, creating recess 804, as shown in diagram 800. For instance, after peeling the protective nitride layer 512, a wet etch (e.g., a pre-clean) with diluted hydrofluoric acid (DHF) can be performed. The pre-clean can also etch the second isolation feature 508 and the oxide mask layer 510.

FIG. 900 provides diagram 900 illustrating results after a downstream wet etching (e.g., a wet etch occurring after epitaxial growth), such as a wet etch for creating dual gate oxide. After the downstream wet etch, recess 804 can increase to form a depression or divot 902 in the first isolation feature 506 results. In an example, junction leakage increases as a size of the divot 902 increases.

As shown in FIGS. 5-9, various processing steps induce a lateral retreat of isolation feature 506 from the first active region 502. In particular, the oxide hard mask wet etch, the results of which are shown in FIG. 7, the epitaxial pre-cleaning/pre-bake shown in FIG. 8, and/or the downstream wet etch process shown in FIG. 9 generate later retreat of the isolation feature 506. The lateral retreat, in turn, facilitates growth of divot 902 and/or rounding of the silicon substrate.

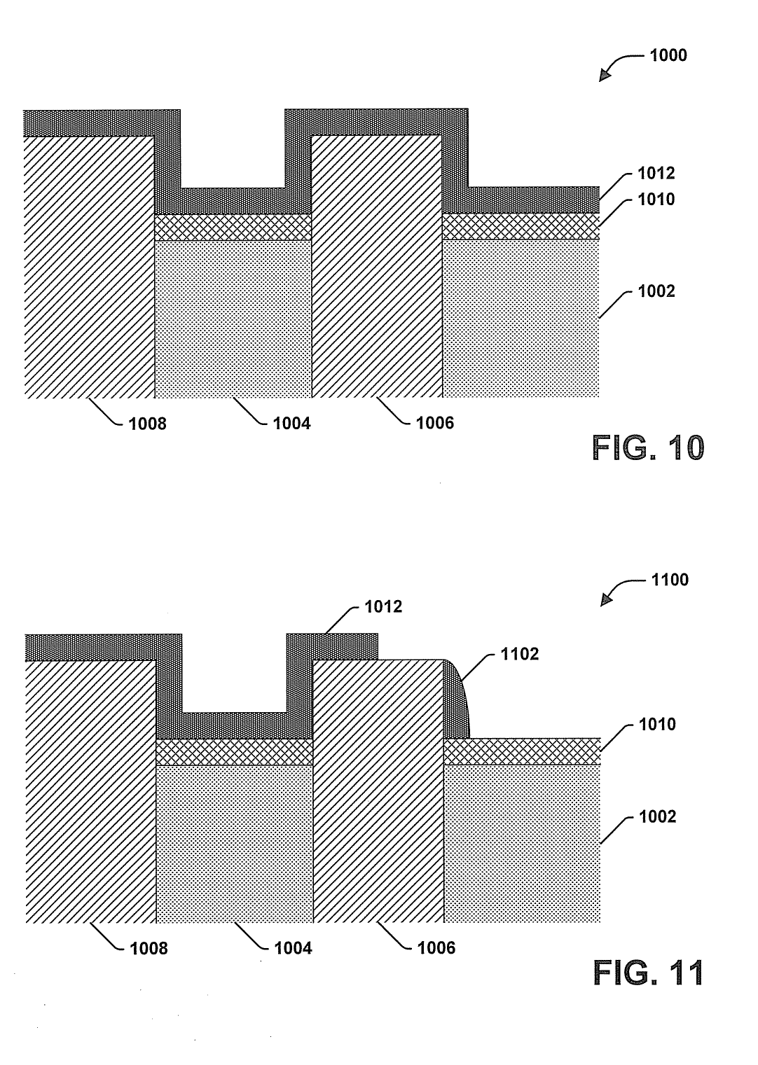

Turning next to FIGS. 10-14, various techniques for fabricating an epitaxial layer are presented. It should be appreciated, however, that the epitaxial layer can be created using any suitable process or combination of processes and that the following description is provided by way of non-limiting example. Further, it should be appreciated that the processes presented in the following description can be utilized to fabricate any suitable product(s) and are not intended to be limited to the semiconductor devices described above.

With reference first to FIG. 10, a first example step of epitaxial layer fabrication in accordance with an embodiment is illustrated via diagram 1000. As diagram 1000 illustrates, upon formation of a first isolation feature 1006 and a second isolation feature 1008, by, for example, STI fabrication, an oxide layer 1010 is deposited on a first active silicon region 1002 and a second active silicon region 1004. Further, a protective nitride layer 1012 can cover the entirety of the isolation features 1006 and 1008 as well as the active regions 1002 and 1004.

In a specific, non-limiting example, it is desired to grow an epitaxial layer on first active region 1002. The first active region 1002 can be a base for a p-type field effect transistor or other similar semiconductor device. Further, the p-type field effect transistor or other semiconductor device built upon the active region 1002 can be incorporated into an integrated circuit such as a SRAM cell. To improve performance of the integrated circuit while facilitating further miniaturization, erosion of the first isolation feature 1006 can be minimized or eliminated during epitaxial growth as described below.

Initially, to grow an epitaxial layer on the first active region 1002, the first active region 1002 is exposed while a remainder of the wafer (e.g., second active region 1004, second isolation feature 1008, etc.) remains protected. Accordingly, etching of the protective nitride layer 1012 by, for example, reactive ion etching, can expose the first active region 1002. Unlike a conventional nitride etching process, a mask can be employed such that, after etching, a spacer 1102 of protective nitride remains along a sidewall of the first isolation feature 1006 and covers a corner at a junction between the first isolation feature 1006 and the first active region 1002. Spacer 1102 facilitates preventing a lateral retreat of isolation feature 1006 from active region 1002. Diagram 1100 of FIG. 1100 illustrates the result after etching the protective nitride layer 1012.

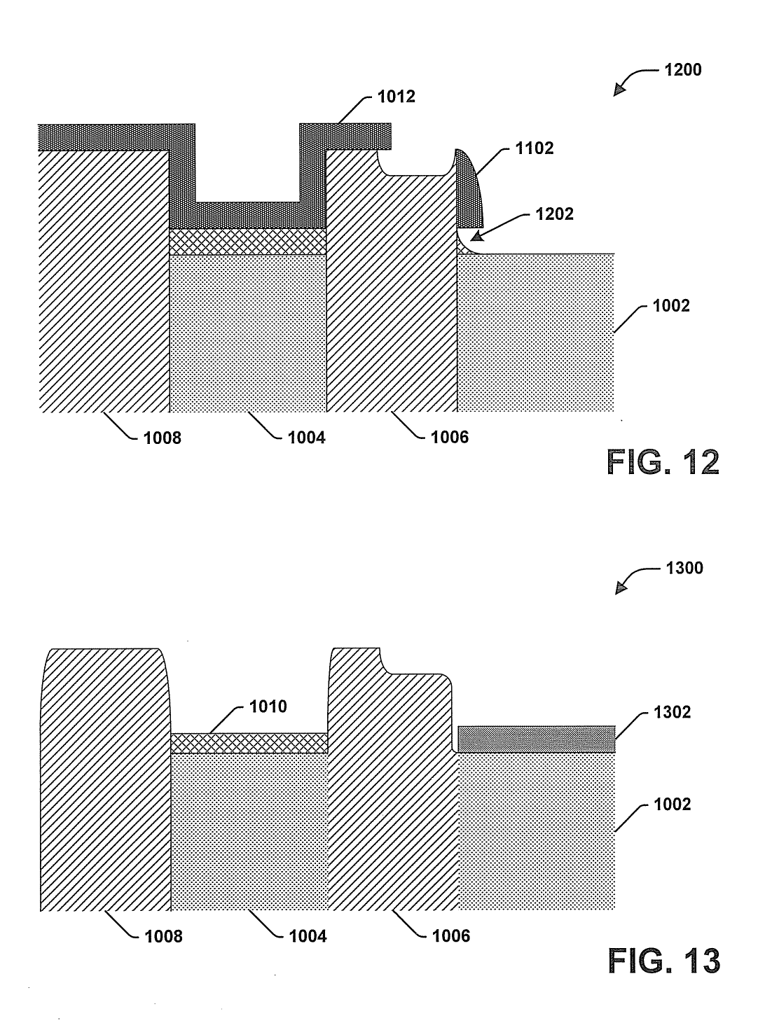

Diagram 1200 of FIG. 12 illustrates a result after a wet etch of the oxide layer 1010 on the first active region 1002. As diagram 1200 illustrates, the wet etch removes the oxide layer 1010 from the first active region 1002. However, spacer 1102 masks the corner between the first isolation feature 1006 and the first active region 1002 such that a portion 1202 of oxide remains in the corner. In addition, spacer 1102 prevents lateral retreat of the first isolation feature 1006 during the wet etch. More particularly, the spacer 1102 prevents a sidewall of the first isolation feature 1006 from retreating away from the active region 1002 during the wet etch process.

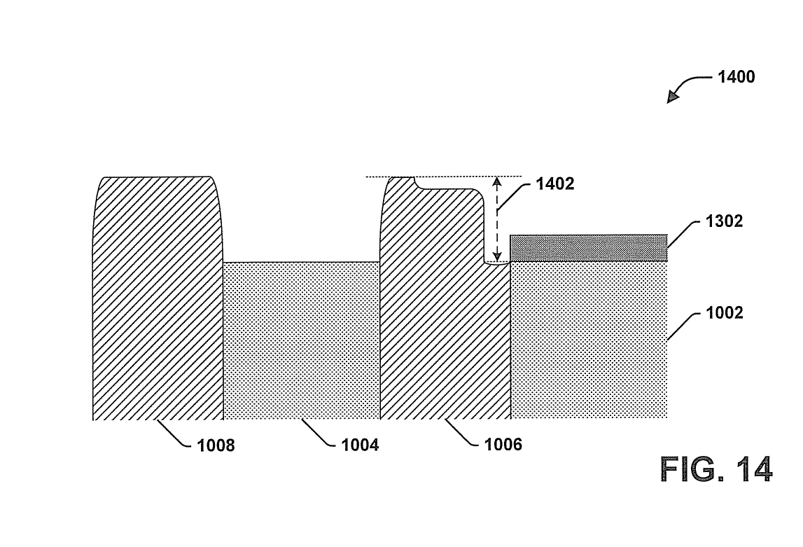

Diagram 1300 of FIG. 13 illustrates a result after deposition of an epitaxial layer 1302 on the first active region 1002. In an example, epitaxial layer 1302 can include a silicon-germanium (SiGe). Accordingly, epitaxial layer 1302 can be referred to as a heteroepitaxial layer. Prior to growing the epitaxial layer 1302, the spacer 1102 of protective nitride can be etched as well as the protective nitride layer 1012. For instance, phosphoric acid (H₃PO₄) can be employed to peel the protective nitride layer 1012 and the spacer 1102. In an example, the nitride layer 1012 is removed prior to epitaxy since phosphoric acid can also etch the epitaxial layer 1302. In addition, pre-cleaning and/or pre-baking steps can occur. For instance, after peeling the protective nitride layer 1012, a wet etch (e.g., a pre-clean) with diluted hydrofluoric acid (DHF) can be performed. The pre-clean can also etch the second isolation feature 1008 and the oxide mask layer 1010. However, the portion 1202 of oxide in the corner guards against removal of the first isolation feature 1006 the junction corner between the first isolation feature 1006 and the first active region 1002. After pre-cleaning and/or pre-baking, epitaxial layer 1302 is deposited on the first active region 1002. As can be seen in FIG. 13, an amount of lateral retreat of first isolation feature 1006 is reduced as compared to the conventional process depicted in FIGS. 5-9.

FIG. 14 provides diagram 1400 illustrating results after a downstream wet etching employed in a process to create a dual gate oxide. As shown in diagram 1400, the spacer 1102 of protective nitride maintains an integrity of the first isolation feature 1006, thus reducing lateral retreat during wet etch processes and preventing the growth of a divot at the corner junction between the first isolation feature 1006 and the first active region 1002. As shown in FIG. 14, according to an embodiment, the first isolation feature 1006 can exhibit an approximate step shape between the first active region 1002 (e.g., a pFET) and the second active region 1004 (e.g., an nFET). In an aspect, a height delta 1402 of the first isolation feature 1006 can exceed 15 nanometers.

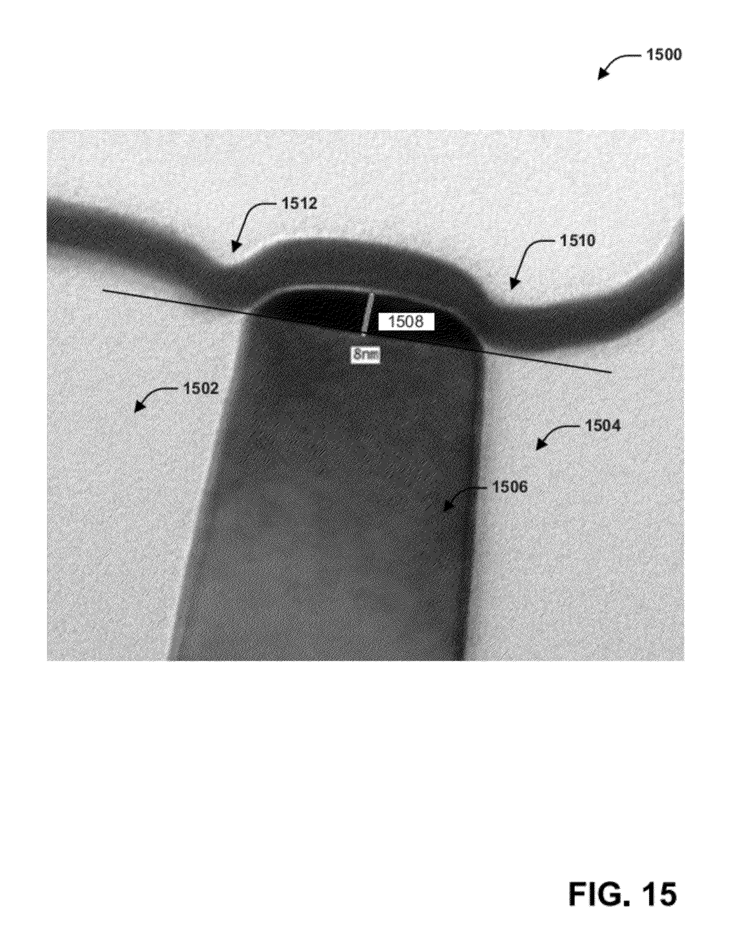

Turning to FIG. 15, depicted is a cross-sectional image 1500 from a transmission electronic microscope of a semiconductor device fabricated in accordance with various embodiments of the subject innovation. In a specific, non-limiting example, the semiconductor device in image 1500 can include a epitaxial layer 1508 fabricated in accordance with the process described above in FIGS. 10-14. However, it is to be appreciated that the semiconductor device can be fabricated with alternative processes.

Depicted in image 1500 are a first isolation feature 1502 and a second isolation 1504. In an example, the isolation features 1502 and 1504 can be fabricated via shallow trench isolation (STI). Between the first isolation feature 1502 and the second isolation feature 1504 is a channel region of a silicon substrate 1506. In an aspect, first isolation feature 1502 and second isolation feature 1504 operate to segregate or separate the channel region of the silicon substrate 1506 from other active regions (not shown) formed on the substrate 1506. An epitaxial layer 1508 is located on top of the channel region of the substrate 1506. According to an embodiment, the epitaxial layer 1508 can be a heteroepitaxial layer. For instance, substrate 1506 can include crystalline silicon and epitaxial layer 1508 includes crystalline silicon-germanium (SiGe).

During the process to grow epitaxial layer 1508 on substrate 1506, the substrate 1506 and isolation features 1502 and 1504 are exposed to a plurality of a masking, etching, and/or cleaning steps. The steps can remove portions of the first isolation feature 1502 and the second isolation feature 1504. However, the integrity of the isolations features 1502 and 1504 can be protected such that the masking, etching, and/or cleaning steps remove portions located at a junction corner between the isolations features 1502 and 1504 and the active region 1506. For example, spacers can be formed along edges of isolation features 1502 and 1504 prior to a wet etching of an oxide hard mask layer. The spacers can prevent a lateral retreat of isolation features 1502 and 1504.

As shown in image 1500, a height of the first isolation feature 1502, at corner 1512, is equal to or greater than a height of an interface between the active region 1506 and the epitaxial layer 1508. Similarly, a height of the second isolation feature 1504 equals or exceeds the height of the interface. Accordingly, the isolation features 1504 and 1502 properly protect against junction leakage as well as shorting risks. In addition, corner rounding of the substrate 1506 is reduced, thus allowing the epitaxial layer 1508 to cover an entirety of the channel region of substrate 1506.

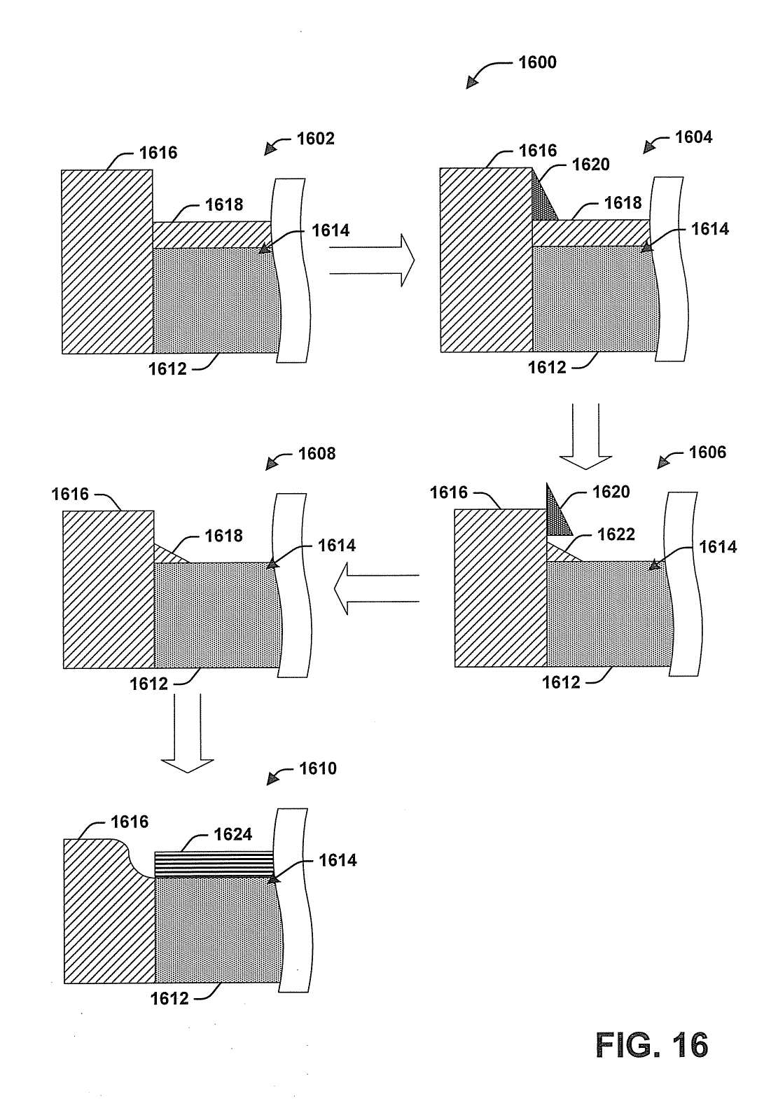

Turning to FIG. 16, an example method 1600 for fabricating a semiconductor as depicted in FIG. 15, for instance, is described. Method 1600 enables formation of an epitaxial layer on a channel region of a silicon substrate with a reduced divot volume and/or divot depth in an isolation feature (e.g., an STI) adjacent to the channel region. In one example, a reduced divot has a bottom surface located less than 20 nanometers below a gate electrode.

At 1602, a portion of semiconductor device is illustrated. The semiconductor device can include a silicon substrate 1612 having an active region or channel region 1614. Adjacent to the silicon substrate is an isolation feature 1616, which can be fabricated according to a shallow trench isolation process, for example. Deposited on the channel region 1614 is an oxide hard mask layer 1618 that facilitates selective formation of an epitaxial layer. At 1604, a spacer 1620 is formed along an edge or sidewall of the isolation feature 1616. The spacer 1620 can comprise a material having a high wet etching selectivity against the oxide hard mask layer 1618. In another aspect, the spacer 1620 can comprise a material having a low wet etching selectivity (e.g., about 1 to 0.8) against the oxide hard mask layer 1618.

At 1606, a wet etching of the oxide hard mask layer 1618 is performed. A remainder portion 1622, of the oxide hard mask layer 1618, can persist after wet etching. As illustrated in FIG. 16, lateral and/or vertical etching of isolation feature 1616 along the edge with the silicon substrate 1612 is prevented by spacer 1620. At 1608, spacer 1620 is removed. At 1610, a result of epitaxial pre-clean/pre-bake and epitaxial deposition is illustrated. An epitaxial layer 1624 is deposited on the channel region 1614 of the silicon substrate 1612. Moreover, the lateral retreat of isolation feature 1616 prevented by spacer 1620 during the wet etching of the oxide hard mask layer 1618 reduces divot propagation as described above with respect to previous figures. In addition, the reducing in divot growth limits rounding of the silicon substrate 1612 during epitaxial pre-clean and/or pre-bake. Accordingly, epitaxial layer 1624 can cover an entirety of channel region 1614.

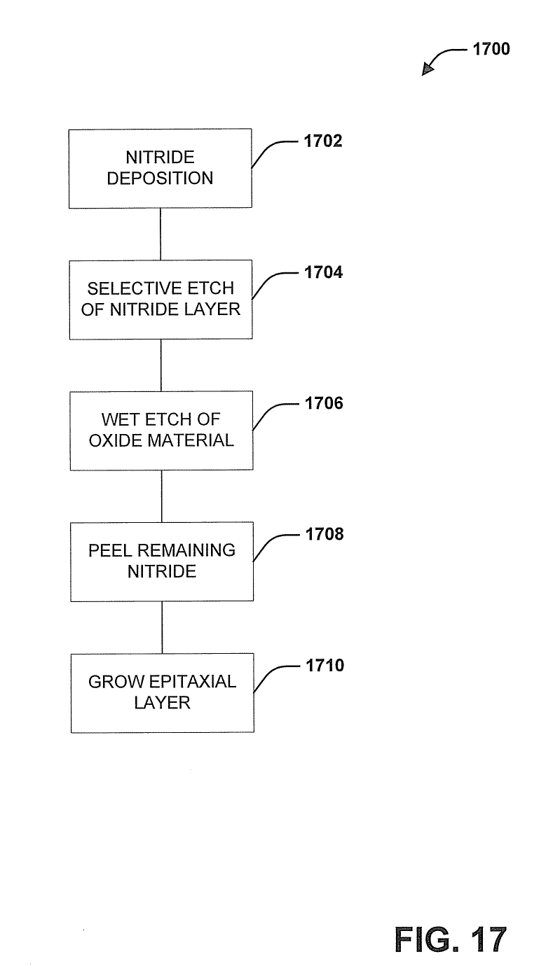

According to an embodiment, an example methodology for conducting at least a partial fabrication of a semiconductor device having an active region and an isolation feature is illustrated by flow diagram 1700 in FIG. 17. As flow diagram 1700 illustrates, an example semiconductor device fabrication methodology can include nitride deposition at 1702, followed by a selective etch of the nitride layer at 1704. In an embodiment, the etch of the nitride layer leaves a portion of the nitride layer along a sidewall of the isolation feature that covers a corner junction between the isolation feature and the active region. The portion of nitride facilitates reducing lateral retreat of the sidewall of the isolation feature. Following the etching of the nitride layer, a wet etch of oxide material can occur at 1706, followed by a peeling of the remaining nitride layer at 1708. Subsequently, an epitaxial layer can be grown upon the active region at 1710. According to an embodiment, the epitaxial layer can be a heteroepitaxial layer such that the epitaxial material includes silicon-germanium while the active region includes crystalline silicon.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A semiconductor device, comprising:
a transistor region comprising:
a semiconductor region formed on a substrate;
an epitaxial layer grown on the semiconductor region; and
an isolation feature adjacent to the semiconductor region such that a corner is formed at an edge between the isolation feature and the semiconductor region,
wherein fabrication of the epitaxial layer results in a first height position of the isolation feature at the corner which is greater than or equal to a second height position of an interface between the epitaxial layer and the semiconductor region.

2. The semiconductor device of claim 1, further comprising a gate electrode on the epitaxial layer, wherein a divot in the isolation feature, adjacent to the semiconductor region, is less than 20 nanometers below the gate electrode.

3. The semiconductor device of claim 1, wherein the epitaxial layer is a heteroepitaxial layer.

4. The semiconductor device of claim 3, wherein the heteroepitaxial layer comprises a silicon-germanium (SiGe) layer.

5. The semiconductor device of claim 1, the epitaxial layer having a thickness of about 8 to 10 nanometers.

6. The semiconductor device of claim 1, wherein the transistor region is a p-type field effect transistor (PFET) region.

7. The semiconductor device of claim 6, wherein the PFET region comprises a pull-up transistor of a static random access memory cell.

8. The semiconductor device of claim 1, wherein fabrication of the epitaxial layer comprises formation of a spacer with a material prior to a wet etching of an oxide hard mask layer.

9. The semiconductor device of claim 8, wherein the spacer is formed at an edge of the isolation feature to prevent horizontal removal of the isolation feature during the wet etching of the oxide hard mask layer.

10. The semiconductor device of claim 8, wherein the oxide hard mask layer facilitates selective formation of the epitaxial layer on the semiconductor region.

11. The semiconductor device of claim 8, wherein the material comprises a high wet etching selectivity against the oxide hard mask layer.

12. The semiconductor device of claim 8, wherein the material comprises a low wet etching selectivity against the oxide hard mask layer.

13. The semiconductor device of claim 12, wherein the material comprises a wet etching selectivity of about 1 to 0.8 against the oxide hard mask layer.

14. The semiconductor device of claim 8, wherein the material of the spacer comprises a nitride material.

15. The semiconductor device of claim 1, wherein the isolation feature being fabricated by a shallow trench isolation technique.

16. The semiconductor device of claim 1, wherein the isolation feature is located between the semiconductor region and a second semiconductor region, wherein a step height delta of the isolation feature between the semiconductor region and the second semiconductor region is at least 15 nanometers.

17. A semiconductor device, comprising:
a static random access memory cell, comprising:
a pull-up transistor area having a p-type field effect transistor area and an isolation area, wherein the p-type field effect transistor area includes an epitaxial layer grown on an active region and a height of the isolation area and a height of an interface between the epitaxial layer and the active region are substantial equal.

18. A method of fabricating a semiconductor device, comprising:
forming a spacer along a sidewall of an isolation feature adjacent to a channel region of a substrate, wherein the sidewall is along an edge between the isolation feature and the channel region;
performing a wet etching of an oxide hard mask layer present on the channel region of the substrate, wherein the spacer prevents a lateral retreat of the isolation feature during the wet etching; and
growing an epitaxial layer on the channel region.

19. The method of claim 18, wherein growing the epitaxial layer comprises forming a heteroepitaxial layer on an entirety of the channel region, include an edge along the isolation feature.

20. The method of claim 18, further comprising removing the spacer prior to growing the epitaxial layer.
